(19) United States
(12) Patent Application Publication
(10) Pub. No.: US 2006/0220082 A1
(43) Pub. Date: Oct. 5, 2006

(54) Semiconductor device and manufacturing method of the same

(75) Inventor: Ko Nakamura, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/190,937

(22) Filed: Jul. 28, 2005

(30) Foreign Application Priority Data
Mar. 17, 2005 (JP) 2005-077888

(51) Int. Cl. H01L 29/94

(52) U.S. Cl. 257/295

(57) ABSTRACT

After a ferroelectric capacitor is formed, a cap film made of Ti or Ir is formed on a top electrode of the ferroelectric capacitor. Thereafter, an alumina film which covers the ferroelectric capacitor is formed as a protective film. Further, a SiO₂ film which covers the ferroelectric capacitor with the alumina film therebetween is formed by a sputtering method. After an interlayer insulating film is formed, holes which reach the cap film and a bottom electrode are respectively formed, and a barrier metal film made of Ti or TiN and a W film are formed therein.

### CROSS-REFERENCE TO RELATED APPLICATIONS

This application is based upon and claims the benefit of priority from the prior Japanese Patent Application No. 2005-077888, filed on Mar. 17, 2005, the entire contents of which are incorporated herein by reference.

### BACKGROUND OF THE INVENTION

1. Field of the Invention

The present invention relates to a semiconductor device suitable for a ferroelectric memory and a manufacturing method of the same.

2. Description of the Related Art

In a conventional ferroelectric memory, Al wirings are connected to a top electrode (IrOₓ electrode) and a bottom electrode (Pt electrode) of a ferroelectric capacitor. It is noted that, for example, in a 0.35 μm design rule, the Al wiring requires a barrier metal film (TiN film) having a thickness of 100 nm or more between an Al film and the respective electrodes. In particular, 150 nm or more is preferable. This is for the purpose of inhibiting an increase in resistance between the top electrode and the Al film and reaction between the bottom electrode and the Al film. The barrier metal film is oxidized by oxygen in the top electrode, and hence a sufficient effect cannot be obtained if the barrier metal film is too thin. On the other hand, in a logic device in which a ferroelectric capacitor does not exist, as a barrier metal film for the Al wiring formed at a similar position, for example, a Ti film having a thickness of 60 nm and a TiN film having a thickness of 30 nm are used. In other words, a semiconductor device including the ferroelectric capacitor requires the thicker barrier metal film.

Moreover, in recent years, a demand for a higher density ferroelectric memory has been increasing. However, with an increase in density, the fabrication of the Al film becomes more difficult. Further, to obtain stable fabrication accuracy, it is preferable to make the thickness of the Al film thin. Hence, in a 0.18 μm or finer design rule, it is difficult to thicken the barrier metal film.

A related art is disclosed in “Extended Abstracts of 1996 International Conference on Solid State Devices and Materials, pp. 800-802” (Non-Patent Document 1).

### SUMMARY OF THE INVENTION

An object of the present invention is to provide a semiconductor device capable of avoiding various problems accompanying a higher density and a manufacturing method of the same.

One of means for realizing stable fabrication is to adopt the same Al wiring structure as in other logic devices also in a ferroelectric memory. However, for this it is necessary to connect W plugs to a top electrode and a bottom electrode instead of directly connecting an Al wiring thereto.

However, to connect the W plug to the top electrode, it is necessary to form a W film under a high-temperature reducing atmosphere. When the W film is formed, hydrogen is produced. Most of the hydrogen is blocked by a TiN film, which is a glue film of the W plug, but when the amount of produced hydrogen increases, hydrogen which gets over a block of the TiN film and reaches the top electrode comes to exist. As a result, IrOₓ which composes the top electrode is reduced, a shrinkage in the volume of the top electrode occurs, and thereby a gap occurs between the glue film and the top electrode. Consequently, the contact resistance of the top electrode becomes unstable.

Incidentally, also in a conventional structure in which an Al wiring is connected to a top electrode, a W plug is connected to a wiring above the Al wiring in some cases. However, in this structure, the contact resistance of the top electrode never becomes a problem. It is thought that this is because the W film is away from the top electrode and plural barrier metals which block the movement of hydrogen exist between the top electrode and the W film.

Further, as a glue film of a W plug, a Ti film or a TiN film is often used. However, if the Ti film or the TiN film is formed on the top electrode made of IrOₓ, the glue film is oxidized by oxygen in IrOₓ, which causes an increase in contact resistance.

Hence, it is thought to form a film of metal such as Pt, Ir, or the like which does not contain oxygen between the top electrode and the glue film. By forming such a film (cap film) between the top electrode and the glue film, the oxidation of the glue film can be prevented, and the contact resistance of the top electrode can be stabilized.

However, when such a cap film is provided only, there is a possibility that hydrogen is produced by catalysis of the cap film, resulting in deterioration in the ferroelectric characteristics of a ferroelectric capacitor. Namely, if a CVD oxide film such as a plasma TEOS film is used as an interlayer insulating film and moisture therein reaches the cap film, hydrogen is produced by the influence of catalytic metal composing the cap film.

Conventionally, an alumina film, a TiO₂ film, or the like is formed as a protective film in a ferroelectric memory, but the penetration of moisture which leads to the production of hydrogen by catalysis is not assumed. If hydrogen is produced, components of a ferroelectric film are reduced by this hydrogen, which causes hydrogen deterioration. Incidentally, since each of the protective films is formed by a sputtering method, its coverage is not so good, and even if the cap film does not exist, the penetration of moisture, which does not matter so much, occurs. However, when the cap film exists, the amount of produced hydrogen with respect to the penetration of the same amount of moisture remarkably increases, so that the conventional protective film cannot be said to be adequate. If the protective film is thickened, it is possible to inhibit the penetration of moisture, but which causes another problem that the fabrication of the protective film (for example, the formation of contact holes) becomes difficult.

Moreover, in Non-Patent Document 1, a method of forming a SiO₂ film as a protective film of a ferroelectric capacitor including a capacitor insulating film made of SBT (SrBi₂Ta₂O₉) by the sputtering method is disclosed. However, as a protective film of a ferroelectric capacitor including a capacitor insulating film made of PZT (Pb(Zr, Ti)O₃), the SiO₂ film cannot be used in place of the alumina film. This is because the alumina film prevents not only the penetration of moisture but also prevents desorption of Pb in the PZT film, whereas the SiO₂ film formed by the sputtering method cannot prevent the desorption of Pb.

Hence, as a result of assiduous study to solve the aforementioned problems, the present inventor has arrived at aspects of the present invention shown below.

In a semiconductor device according to the present invention, a ferroelectric capacitor is covered with a first insulating film which inhibits penetration of moisture into the ferroelectric capacitor. Further, the ferroelectric capacitor is covered with a second insulating film with higher fabricability than the first insulating film which inhibits penetration of moisture into the ferroelectric capacitor with the first insulating film therebetween.

In a manufacturing method of a semiconductor device according to the present invention, after a ferroelectric capacitor is formed, a first insulating film which covers the ferroelectric capacitor and inhibits penetration of moisture into the ferroelectric capacitor is formed. Then, a second insulating film with higher fabricability than the first insulating film which covers the ferroelectric capacitor with the first insulating film therebetween and inhibits penetration of moisture into the ferroelectric capacitor is formed.

### BRIEF DESCRIPTION OF THE DRAWINGS

FIG. 1 is a circuit diagram showing the configuration of a memory cell array of a ferroelectric memory to be manufactured by a method according to an embodiment of the present invention; and

FIG. 2A to FIG. 2I are sectional views showing a manufacturing method of a ferroelectric memory according to the embodiment of the present invention step by step.

### DETAILED DESCRIPTION OF THE PREFERRED EMBODIMENTS

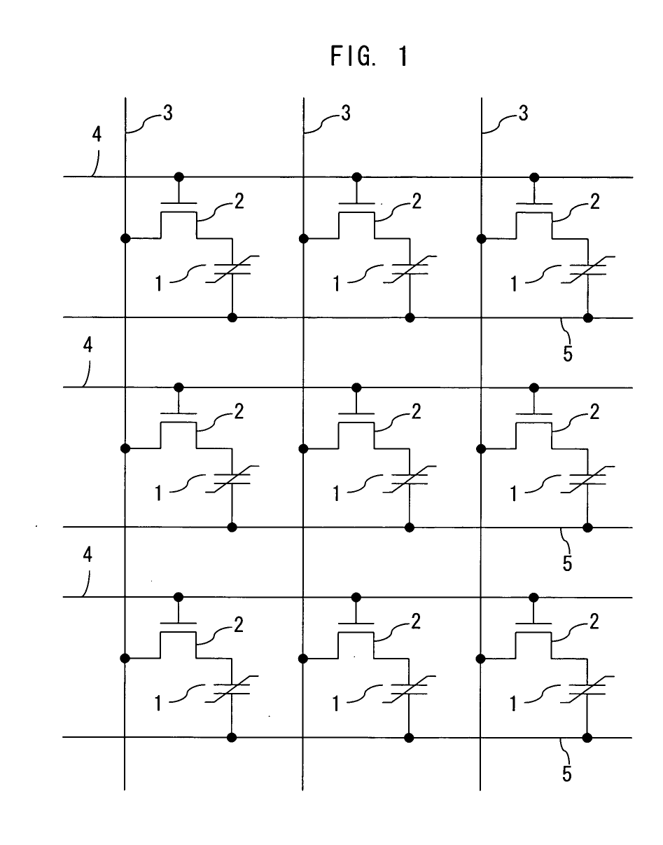

An embodiment of the present invention will be specifically described below with reference to the attached drawings. FIG. 1 is a circuit diagram showing the configuration of a memory cell array of a ferroelectric memory (semiconductor device) to be manufactured by a method according to the embodiment of the present invention.

In this memory cell array, plural bit lines 3 which extend in one direction and plural word lines 4 and plate lines 5 which extend in a direction perpendicular to the direction in which the bit lines 3 extend are provided. Additionally, plural memory cells of the ferroelectric memory are arranged in an array form in such a manner as to match a grid composed of these bid lines 3, word lines 4, and plate lines 5. In each memory cell, a ferroelectric capacitor 1 and a MOS transistor 2 are provided.

A gate of the MOS transistor 2 is connected to the word line 4. One source/drain of the MOS transistor 2 is connected to the bit line 3, and the other source/drain thereof is connected to one electrode of the ferroelectric capacitor 1. The other electrode of the ferroelectric capacitor 1 is connected to the plate line 5. Incidentally, each of the word lines 4 and the plate lines 5 is shared by plural MOS transistors 2 arranged in the same direction as the direction in which the line extends. Similarly, each of the bit lines 3 is shared by plural MOS transistors 2 arranged in the same direction as the direction in which the line extends. The direction in which the word lines 4 and the plate lines 5 extend and the direction in which the bit lines 3 extend are sometimes called a row direction and a column direction, respectively.

In the memory cell array of the ferroelectric memory thus configured, data are stored according to the polarization state of a ferroelectric film provided in the ferroelectric capacitor 1.

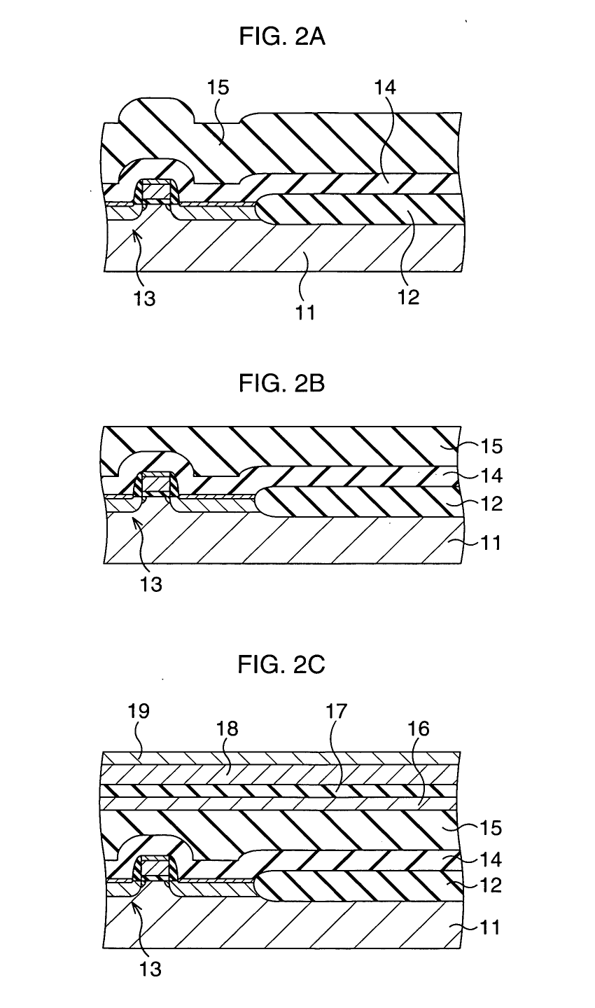

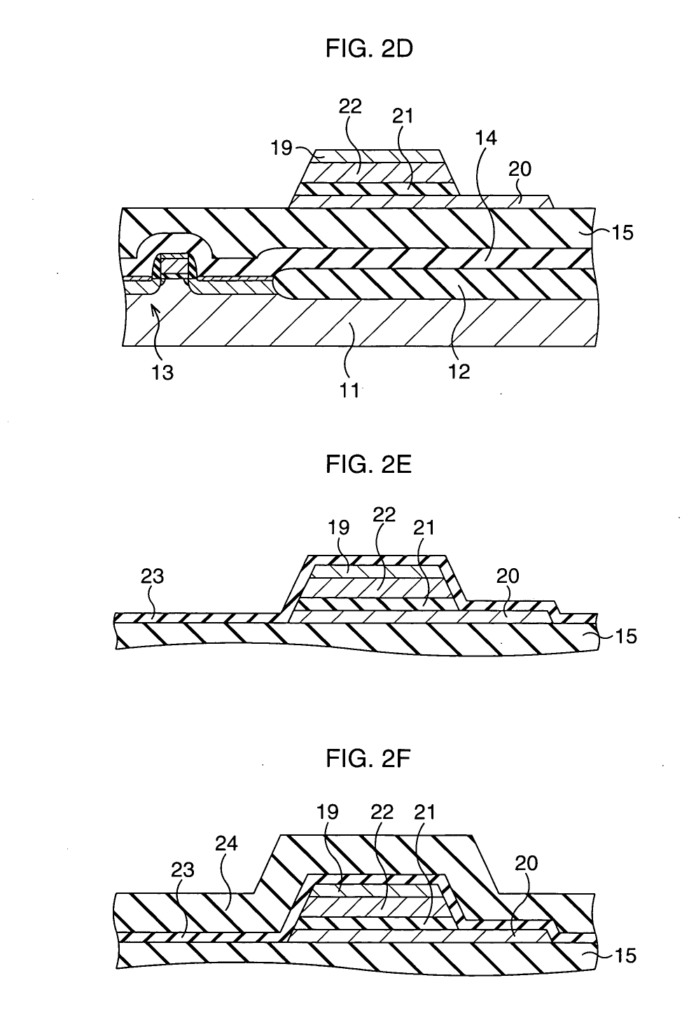

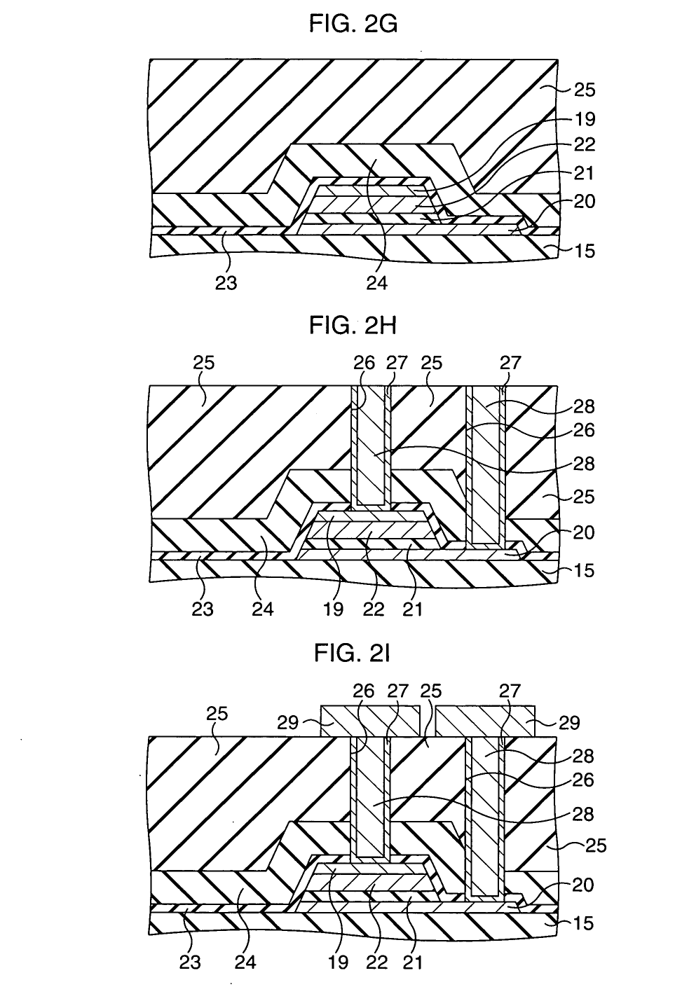

Next, the embodiment of the present invention will be described. Note that here, for convenience, a cross-sectional structure of the ferroelectric memory will be described with a manufacturing method thereof. FIG. 2A to FIG. 2I are sectional views showing a manufacturing method of the ferroelectric memory (semiconductor device) according to the embodiment of the present invention step by step.

In the present embodiment, first, as shown in FIG. 2A, an element isolation insulating film 12 is formed on the surface of a silicon substrate 11. Then, by selectively doping each of predetermined active regions with an impurity, wells (not shown) are formed. The conductivity type of the silicon substrate 11 may be either a p-type or an n-type. Subsequently, a MOS transistor 13 having an LDD structure is formed in the active region. The MOS transistor corresponds to the MOS transistor 2 in FIG. 1. Thereafter, an oxidation preventing film 14 which covers the MOS transistor 13 is formed by a CVD method. As the oxidation preventing film 14, for example, a SION film is formed. Then, a SiO₂ film 15, for example, is formed on the oxidation preventing film 14 by a CVD method. Incidentally, when the SiO₂ film 15 is formed, for example, TEOS (tetraethylorthosilicate) is used as a reactive gas.

Subsequently, as shown in FIG. 2B, the Sio₂ film is planarized by polishing its upper surface by a chemical mechanical polishing (CMP) method.

Thereafter, as shown in FIG. 2C, a Pt film 16 (bottom electrode film) which becomes a bottom electrode is formed on the SiO₂ film 15 by a sputtering method. Then, as shown in FIG. 2C also, a PLZT ((Pb, La)(Zr, Ti)O₃) film 17 (ferroelectric film) which becomes a capacitor insulating film of the ferroelectric capacitor is formed in an amorphous state on the Pt film 16 by a sputtering method. Subsequently, as shown in FIG. 2C also, a iridium oxide (IrO₂) film 18 (top electrode film) which becomes a top electrode of the ferroelectric capacitor is formed on the PLZT film 17 a the sputtering method. Further, as shown in FIG. 2C also, a cap film 19 is formed on the IrO₂ film 18. As the cap film, for example, a Pt film, an Ir film, or the like is formed.

Thereafter, as shown in FIG. 2D, a resist pattern (not shown) having a pattern shape of the top electrode of the ferroelectric capacitor is formed on the cap film 19, and using the resist pattern as a mask, the cap film 19 and the IrO₂ film 18 are etched. As a result, as shown in FIG. 2D, a top electrode 22 is obtained from the IrO₂ film 18. Then, the resist pattern is removed, a new resist pattern (not shown) having a pattern shape of the capacitor insulating film of the ferroelectric capacitor is formed, and using the resist pattern as a mask, the PLZT film 17 is etched. As a result, as shown in FIG. 2D, a capacitor insulating film 21 is obtained from the PLTZ film 17. Subsequently, the resist pattern is removed, a new resist pattern (not shown) having a pattern shape of the bottom electrode of the ferroelectric capacitor is formed, and using the resist pattern as a mask, the Pt film 16 is etched. As a result, as shown in FIG. 2D, a bottom electrode 20 is obtained from the Pt film 16, and thus the ferroelectric capacitor is formed. The ferroelectric capacitor corresponds to the ferroelectric capacitor 1 in FIG. 1.

Thereafter, as shown in FIG. 2E, an alumina film 23 which covers the ferroelectric capacitor is formed as a protective film by a sputtering method.

Then, as shown in FIG. 2F, a silicon oxide film 24 which covers the ferroelectric capacitor with the alumina film 23 therebetween is formed by a sputtering method. In place of the alumina film 23, a Ti oxide film may be formed.

Subsequently, as shown in FIG. 2G, an interlayer insulating film 25 is formed over the entire surface. As the interlayer insulating film 25, for example, a silicon oxide film is formed by a CVD method. Thereafter, the interlayer insulating film 25 is planarized.

Then, as shown in FIG. 2H, holes 26 which reach the cap layer 19 and the bottom electrode 20 are respectively formed in the interlayer insulating film 25, and a glue film 27 and a W film 28 are formed in each of the holes 26. Namely, W plugs are formed. As the glue film 27, for example, a Ti film or a TiN film is formed.

Subsequently, as shown in FIG. 2I, a wiring 29 connected to the W plugs is formed on the interlayer insulating film 25. A wiring including, for example, a barrier metal film and an Al film is formed as the wiring 29.

Although not shown, formation of an interlayer insulating film, formation of contact plugs, formation of wirings in the second and subsequent layers from the bottom, and so on are further performed. Thereafter, a cover film, for example, made of a TEOS oxide film and a SiN film is formed, and thus the ferroelectric memory including the ferroelectric capacitor is completed.

In the aforementioned embodiment, the silicon oxide film 24 formed by the sputtering method does not contain moisture and it is dense. Therefore, similarly to the alumina film 23, the silicon oxide film 24 can inhibit the penetration of moisture into the ferroelectric capacitor from its surroundings. Accordingly, the penetration of moisture is inhibited by the alumina film 23 and the silicon oxide film 24, leading to a marked reduction in the amount of penetration of moisture, whereby even if the cap film 19 containing catalytic metal exists, deterioration in the ferroelectric characteristics of the PLZT film 17 can be inhibited. Further, since the alumina film 23 exists, the desorption of Pb from the PLZT film 17 does not occur. Furthermore, the fabricability of the silicon oxide film 24 is better than that of the alumina film 23, and therefore there is no inconvenience when an opening is formed later.

Incidentally, it is desirable that the thickness of the silicon oxide film 24 formed by the sputtering method be approximately not less than 100 nm nor more than 200 nm. If the thickness of the silicon oxide film 24 is less than 100 nm, there is a possibility that the penetration of moisture cannot be fully inhibited. Moreover, the deposition rate in the sputtering method is lower than that in the CVD method. Further, the step coverage of the silicon oxide film 24 is lower than that of the silicon oxide film (interlayer insulating film 25) formed by the CVD method. Hence, it is desirable that the thickness of the silicon oxide film 24 be 200 nm or less.

Incidentally, the present invention is not limited to the aforementioned embodiment. For example, as the ferroelectric materials, for example, SBT, SBTN, and the like may be used in addition to PZT or PLZT. Furthermore, the method of depositing the ferroelectric film is not limited to the MOCVD method, and other depositing methods such as a sol-gel method, a sputtering method, and so on may be used. Moreover, as the ferroelectric capacitor, not only a ferroelectric capacitor having a planar structure but also that having a stack structure may be formed.

According to the present invention, a ferroelectric capacitor is covered with a first and second insulating films, whereby most of moisture cannot reach the ferroelectric capacitor. Accordingly, even if a cap film containing catalytic metal is provided, hydrogen deterioration does not tend to occur. When a PZT film is used as a capacitor insulating film of the ferroelectric capacitor, the outward diffusion of Pb is inhibited when an alumina film or the like is used as the first insulating film. Moreover, since a film having higher fabricability than the first insulating film is used as the second insulating film, higher fabricability can be obtained than when the first insulating film is only thickened.

The present embodiment is to be considered in all respects as illustrative and no restrictive, and all changes which come within the meaning and range of equivalency of the claims are therefore intended to be embraced therein. The invention may be embodied in other specific forms without departing from the spirit or essential characteristics thereof.

What is claimed is:

1. A semiconductor device, comprising
a ferroelectric capacitor;
a first insulating film covering said ferroelectric capacitor and inhibiting penetration of moisture into said ferroelectric capacitor; and
a second insulating film with higher fabricability than said first insulating film covering said ferroelectric capacitor with said first insulating film therebetween and inhibiting penetration of moisture into said ferroelectric capacitor.

2. The semiconductor device according to claim 1, wherein said first insulating film is an Al oxide film or a Ti oxide film.

3. The semiconductor device according to claim 1, wherein said second insulating film is a Si oxide film.

4. The semiconductor device according to claim 1, wherein said second insulating film has a thickness between 100 nm and 200 nm.

5. The semiconductor device according to claim 1, further comprising a metal film formed on said ferroelectric capacitor and covered with said first insulating film.

6. The semiconductor device according to claim 5, wherein said metal film is a Pt film or an Ir film.

7. The semiconductor device according to claim 5, further comprising an interlayer insulating film formed on said second insulating film, wherein
an opening which reaches said metal film is formed in said interlayer insulating film, said second insulating film, and said first insulating film, and
a barrier metal film and a W film are formed in the opening.

8. The semiconductor device according to claim 7, wherein the barrier metal film is a Ti film or a TiN film.

9. A manufacturing method of a semiconductor device, comprising the steps of:
forming a ferroelectric capacitor;
forming a first insulating film which covers the ferroelectric capacitor and inhibits penetration of moisture into the ferroelectric capacitor; and
forming a second insulating film with higher fabricability than the first insulating film which covers the ferroelectric capacitor with the first insulating film therebetween and inhibits penetration of moisture into the ferroelectric capacitor.

10. The manufacturing method of the semiconductor device according to claim 9, wherein as the first insulating film, an Al oxide film or a Ti oxide film is formed.

11. The manufacturing method of the semiconductor device according to claim 9, wherein the first insulating film is formed by a sputtering method.

12. The manufacturing method of the semiconductor device according to claim 9, wherein as the second insulating film, a Si oxide film is formed.

13. The manufacturing method of the semiconductor device according to claim 12, wherein the second insulating film is formed by a sputtering method.

14. The manufacturing method of the semiconductor device according to claim 9, wherein the second insulating film has a thickness between 100 nm and 200 nm.

15. The manufacturing method of the semiconductor device according to claim 9, further comprising the step of forming a metal film on the ferroelectric capacitor before said step of forming the first insulating film.

16. The manufacturing method of the semiconductor device according to claim 15, wherein as the metal film, a Pt film or an Ir film is formed.

17. The manufacturing method of the semiconductor device according to claim 15, further comprising the steps of:
forming an interlayer insulating film on the second insulating film;
forming an opening which reaches the metal film in the interlayer insulating film, the second insulating film, and the first insulating film; and
forming a barrier metal film and a W film in the opening.

18. The manufacturing method of the semiconductor device according to claim 17, wherein as the barrier metal film, a Ti film or a TiN film is formed.

19. The manufacturing method of the semiconductor device according to claim 17, wherein as the interlayer insulating film, a Si oxide film is formed by a CVD method.
